(19) United States
(12) Patent Application Publication
(10) Pub. No.: US 2017/0062538 A1
(43) Pub. Date: Mar. 2, 2017

(54) THIN FILM TRANSISTOR, METHOD OF MANUFACTURING THE SAME, AND ORGANIC LIGHT-EMITTING DISPLAY

(71) Applicant: Samsung Display Co., Ltd., Yongin-City (KR)

(72) Inventors: Junghyun Kim, Yongin-si (KR); Kiwan Ahn, Yongin-si (KR)

(21) Appl. No.: 15/019,048

(22) Filed: Feb. 9, 2016

(30) Foreign Application Priority Data
Aug. 24, 2015 (KR) 10-2015-0118878

(51) Int. Cl. H01L 27/32; H01L 27/12; H01L 29/66; H01L 51/52

(52) U.S. Cl. CPC H01L 27/3262; H01L 27/3265; H01L 27/3248; H01L 51/529; H01L 27/1218; H01L 29/66757; H01L 27/1222; H01L 27/1274; H01L 2227/323

(57) ABSTRACT

A thin film transistor array substrate comprises a substrate including a driving transistor region and a switching transistor region, an additional layer disposed in the driving transistor region on the substrate, a buffer layer disposed on the substrate to cover the additional layer, and a driving transistor and a switching transistor disposed in the driving transistor region and the switching transistor region, respectively, on the buffer layer.

### CLAIM OF PRIORITY

This application claims priority to and claims all benefits accruing under 35 U.S.C. §119 from an application earlier filed in the Korean Patent Application No. 10-2015-0118878 filed on Aug. 24, 2015 in the Korean Intellectual Property Office, the disclosure of which is incorporated herein in its entirety by reference thereto.

### BACKGROUND OF THE INVENTION

Field of the Invention

The present invention relates to a thin film transistor array substrate, a method of manufacturing the same, and an organic light-emitting display apparatus having the thin film transistor array substrate, and more particularly, to a thin film transistor array substrate having an improved driving range of a thin film transistor, a method of manufacturing the same, and an organic light-emitting display apparatus having the thin film transistor array substrate.

Description of the Related Art

A display apparatus, such as an organic light-emitting display apparatus and a liquid crystal display apparatus, includes a thin film transistor (TFT), a capacitor, and a plurality of wirings. A substrate usable in manufacturing the display apparatus may be formed with fine patterns such as the thin film transistor (TFT), the capacitor, and the wirings, and the display apparatus operates according to complicated connections between the thin film transistor, the capacitor, and the wirings.

Recently, according to increased demands for a compact display apparatus having a high resolution, demands for an efficient space arrangement and connecting structure among the thin film transistor (TFT), the capacitor, and the wirings of the display apparatus have also increased.

Meanwhile, the organic light-emitting display apparatus includes a hole injection electrode, an electron injection electrode, and an organic light-emitting device having an organic light-emitting layer which is disposed between the hole injection electrode and the electron injection electrode. The organic light-emitting display apparatus is a self-luminous type of display apparatus which emits light when electrons of the electron injection electrode and holes of the hole injection electrode combine in the organic light-emitting layer so as to generate excitons, and when the generated excitons are changed from an excited state to a ground state.

Since the organic light-emitting display apparatus of the self-luminous type does not need a back light source, the organic light-emitting display apparatus operates with a low voltage and becomes thin and lightweight. Since the organic light-emitting display apparatus has excellent characteristics in viewing angles, contrast and response times, the organic light-emitting display apparatus is applied to various apparatuses, for example, a personal portable device, such as an MP3 player and a smart phone, and a television (TV).

The organic light-emitting display apparatus may include a driving circuit to drive an organic light-emitting device and a driving transistor to control a current flowing through the organic light-emitting device.

The driving transistor includes a predetermined driving range. When the driving range is widened, the gradation of light emitted from the organic light-emitting device may be fine-controlled so as to increase the resolution of the organic light-emitting display apparatus and to improve display quality. However, when a channel area included in the thin film transistor is lengthened, it is difficult to realize an organic light-emitting display apparatus having a high resolution since a space occupied by the lengthened channel area is enlarged.

### SUMMARY OF THE INVENTION

One or more exemplary embodiments of the invention include a thin film transistor array substrate having an improved driving range of a thin film transistor, a method of manufacturing the same, and an organic light-emitting display apparatus having the same.

Additional aspects will be set forth in part in the description which follows and, in part, will be apparent from the description, or may be learned by practice of the presented embodiments of the invention.

According to one or more exemplary embodiments of the invention, a thin film transistor array substrate may include a substrate including a driving transistor region and a switching transistor region, an additional layer in the driving transistor region on the substrate, a buffer layer covering the additional layer on the substrate, and a driving transistor and a switching transistor in the driving transistor region and the switching transistor region, respectively, on the buffer layer.

According to one or more exemplary embodiments of the invention, the additional layer may have a thermal conductivity in a range from about 104 W/m·° C. through about 106 W/m·° C.

According to one or more exemplary embodiments of the invention, the additional layer may have a thermal conductivity higher than that of the buffer layer.

According to one or more exemplary embodiments of the invention, the additional layer may have a thermal conductivity higher than that of at least one material selected from a group consisting of silicon oxide (SiO₂), silicon nitride (SiNₓ), amorphous silicon, and polysilicon.

According to one or more exemplary embodiments of the invention, the additional layer may include at least one selected from a group consisting of siloxane-based materials, graphene, carbon nanotubes, aluminum (Al), molybdenum (Mo), chrome (Cr), silver (Ag), and copper (Cu).

According to one or more exemplary embodiments of the invention, the buffer layer may include at least one of silicon oxide (SiO₂) and silicon nitride (SiNₓ).

According to one or more exemplary embodiments of the invention, the driving transistor may include a driving active layer on the buffer layer so as to correspond to the additional layer and a driving gate electrode on a portion of the driving active layer, The switching transistor may include a switching active layer on the buffer layer and a switching gate electrode on a portion of the switching active layer, and the driving active layer may include crystals having non-uniform dimensions more than those of the switching active layer.

According to one or more exemplary embodiments of the invention, the thin film transistor array substrate may further include a capacitor overlapping the driving transistor in a direction perpendicular to the substrate, and the capacitor may include the driving gate electrode functioning as a lower electrode of the capacitor, and an upper electrode corresponding to the driving gate electrode.

According to one or more exemplary embodiments of the invention, the driving active layer may include a driving source area, a driving drain area spaced apart from the driving source area, and a driving channel area between the driving source area and the driving drain area, and the additional layer may be between the substrate and at least a portion of the driving channel area.

According to one or more exemplary embodiments of the invention, a manufacturing method of a thin film transistor array substrate includes forming an additional layer in a driving transistor region on a substrate having the driving transistor region and a switching transistor region, forming a buffer layer on the substrate so as to cover the additional layer, forming an amorphous silicon layer on the buffer layer, irradiating the amorphous silicon layer with a laser beam so as to crystallize the amorphous silicon layer into polysilicon, patterning a polysilicon layer and forming a driving semiconductor layer and a switching semiconductor layer in the driving transistor region and the switching transistor region, respectively, forming a lower gate insulation film so as to cover the driving semiconductor layer and the switching semiconductor layer, forming a driving gate electrode and a switching gate electrode on the lower gate insulation film so as to correspond to a portion of the driving semiconductor layer and a portion of the switching semiconductor layer, respectively, doping the driving semiconductor layer and the switching semiconductor layer by using the driving gate electrode and the switching gate electrode as corresponding masks, forming a driving active layer including a driving source area, a driving drain area and a driving channel area, and forming a switching active layer including a switching source area, a switching drain area and a switching channel area.

According to one or more exemplary embodiments of the invention, the forming of the additional layer may include forming a thermal conductive material on the substrate, removing the thermal conductive material from the switching transistor region, and forming the additional layer so as to correspond to the driving transistor region.

According to one or more exemplary embodiments of the invention, the additional layer may have a thermal conductivity higher than that of the buffer layer.

According to one or more exemplary embodiments of the invention, the additional layer may have a thermal conductivity higher than that of at least one material selected from a group consisting of amorphous silicon, polysilicon, silicon oxide (SiO₂), and silicon nitride (SiNₓ).

According to one or more exemplary embodiments of the invention, the additional layer may have a thermal conductivity in a range from about 104 W/m·° C. through about 106 W/m·° C.

According to one or more exemplary embodiments of the invention, the additional layer may include at least one selected from a group consisting of siloxane-based materials, graphene, carbon nanotubes, aluminum (Al), molybdenum (Mo), chrome (Cr), silver (Ag), and copper (Cu).

According to one or more exemplary embodiments of the invention, the buffer layer may include at least one of silicon oxide (SiO₂) and silicon nitride (SiNₓ).

According to one or more exemplary embodiments of the invention, an organic light emitting display apparatus may include a substrate including a driving transistor region and a switching transistor region, an additional layer in the driving transistor region on the substrate, a buffer layer covering the additional layer on the substrate, a driving transistor and a switching transistor in the driving transistor region and the switching transistor region, respectively, on the buffer layer, a pixel electrode electrically connected to the driving transistor, a common electrode corresponding to the pixel electrode, and an organic emission layer between the pixel electrode and the common electrode.

According to one or more exemplary embodiments of the invention, the additional layer may have a thermal conductivity in a range from about 104 W/m·° C. through about 106 W/m·° C.

According to one or more exemplary embodiments of the invention, the driving transistor may include a driving active layer on the buffer layer so as to correspond to the additional layer and a driving gate electrode on a portion of the driving active layer. The switching transistor may include a switching active layer on the buffer layer and a switching gate electrode on a portion of the switching active layer, and the driving active layer may include crystals having non-uniform dimensions which are greater than those of the switching active layer.

According to one or more exemplary embodiments of the invention, the organic light emitting display apparatus may include a capacitor overlapping the driving transistor in a direction perpendicular to the substrate, and the capacitor may include the driving gate electrode functioning as a lower electrode of the capacitor and an upper electrode corresponding to the driving gate electrode.

### BRIEF DESCRIPTION OF THE DRAWINGS

These and/or other aspects will become apparent and more readily appreciated from the following description of the exemplary embodiments of the invention, taken in conjunction with the accompanying drawings in which:

FIG. 1 is an equivalent circuit diagram of a pixel of an organic light-emitting display apparatus;

FIG. 2 is a cross-sectional view schematically illustrating an organic light-emitting display apparatus according to one exemplary embodiment of the invention;

FIGS. 3A thru 3F are cross-sectional views illustrating a manufacturing method of the organic light-emitting display apparatus of FIG. 2;

FIG. 4 is an equivalent circuit diagram of a pixel of an organic light-emitting display apparatus according to another exemplary embodiment of the invention; and

FIG. 5 is a cross-sectional view schematically illustrating an organic light-emitting display apparatus according to another exemplary embodiment of the invention.

### DETAILED DESCRIPTION OF THE INVENTION

The present exemplary embodiments of the invention may have different forms and embodiments of the invention and should not be construed as being limited to the descriptions set forth herein. Accordingly, the exemplary embodiments of the invention are merely described below by referring to the figures in order to explain aspects of the present description.

Reference will now be made in detail to exemplary embodiments of the invention, examples of which are illustrated in the accompanying drawings, wherein like reference numerals refer to like elements throughout.

It will be understood that, although the terms “first”, “second”, etc. may be used herein to describe various components, these components should not be limited by these terms. These terms are only used to distinguish one component from another.

As used herein, the singular forms “a,” “an” and “the” are intended to include the plural forms as well unless the context clearly indicates otherwise.

It will be further understood that the terms “comprises” and/or “comprising” used herein specify the presence of stated features or components, but do not preclude the presence or addition of one or more other features or components.

It will be understood that, when a layer, region or component is referred to as being “formed on,” another layer, region or component, it can be directly or indirectly formed on the other layer, region or component. That is, for example, intervening layers, regions or components may be present.

In exemplary embodiments of the invention, when a film, layer, region and component are connected to each other, “connection” may include a direct connection between the film, layer, region and component, and may also include an indirect connection between the film, layer, region and component through another film, layer, region or component. For example, when the present disclosure states that a film, layer, region and component are electrically connected to each other, the connection may include not only a direct connection between the film, layer, region and component, but also an indirect connection between the film, layer, region and component though another film, layer, region or component.

Sizes of elements in the drawings may be exaggerated for convenience of explanation. In other words, since sizes and thicknesses of components in the drawings are arbitrarily illustrated for convenience of explanation, the following embodiments of the invention are not limited thereto.

When a certain embodiment of the invention may be implemented differently, a specific process order may be performed differently from the described order. For example, two consecutively described processes may be performed substantially at the same time or may be performed in an order opposite to the described order.

In drawings, although an active matrix type organic light-emitting display apparatus including a 2Tr-1Cap structure, which has two thin film transistors TFTs and one capacitor in a single pixel, and a 7Tr-1Cap structure, which has seven thin film transistors TFTs and one capacitor in a single pixel, is illustrated, the present invention is not limited thereto. Accordingly, the organic light-emitting display apparatus may include a plurality of thin film transistors and one or more capacitors in each pixel, and also may have various structures, for example, including an additional wiring or omitting a conventional wiring. The pixel may mean a minimum unit to display an image, and the organic light-emitting display apparatus may display an image by using a plurality of pixels.

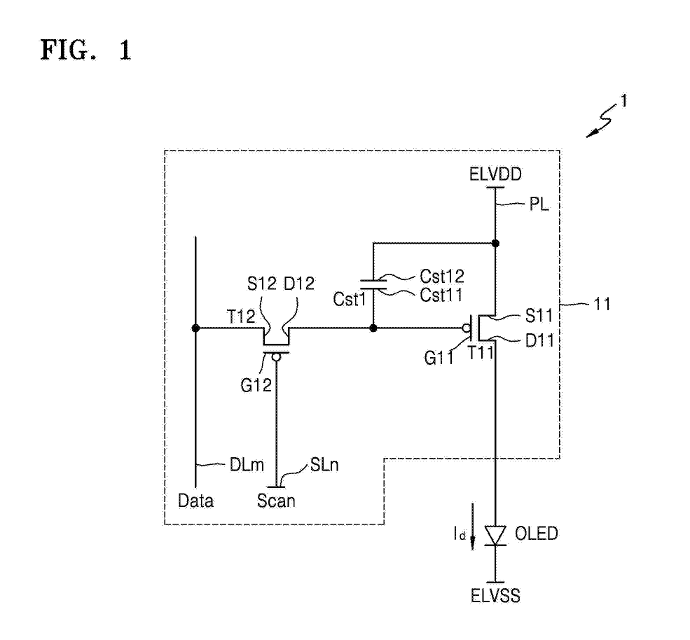

FIG. 1 is an equivalent circuit diagram of a pixel of an organic light-emitting display apparatus.

Referring to FIG. 1, the organic light-emitting display apparatus 1 according to one embodiment of the invention may include a thin film transistor array substrate 11 and an organic light-emitting device OLED arranged on the thin film transistor array substrate 11. The organic light-emitting display apparatus 1 may include a plurality of pixels, each having the organic light-emitting device OLED. The thin film transistor array substrate 11 may include a pixel circuit to drive each pixel and a plurality of wirings to apply electrical signals to the pixel circuit.

The wirings may include a scan line SLn to transmit a scan signal Scan, a data line DLm to transmit a data signal Data, and a driving voltage line PL to transmit a driving voltage ELVDD. Each pixel may be disposed at a position where the scan line SLn extending in a first direction intersects the data line DLm extending in a second direction.

Each pixel may include the organic light-emitting device OLED and the pixel circuit to receive signals through the wirings and to drive the organic light-emitting device OLED. According to one embodiment of the invention, the pixel circuit may include two transistors T11 and T12 and one capacitor Cst1. The transistor T11 may be referred to as a driving transistor T11 and the transistor T12 may be referred to as a switching transistor T12.

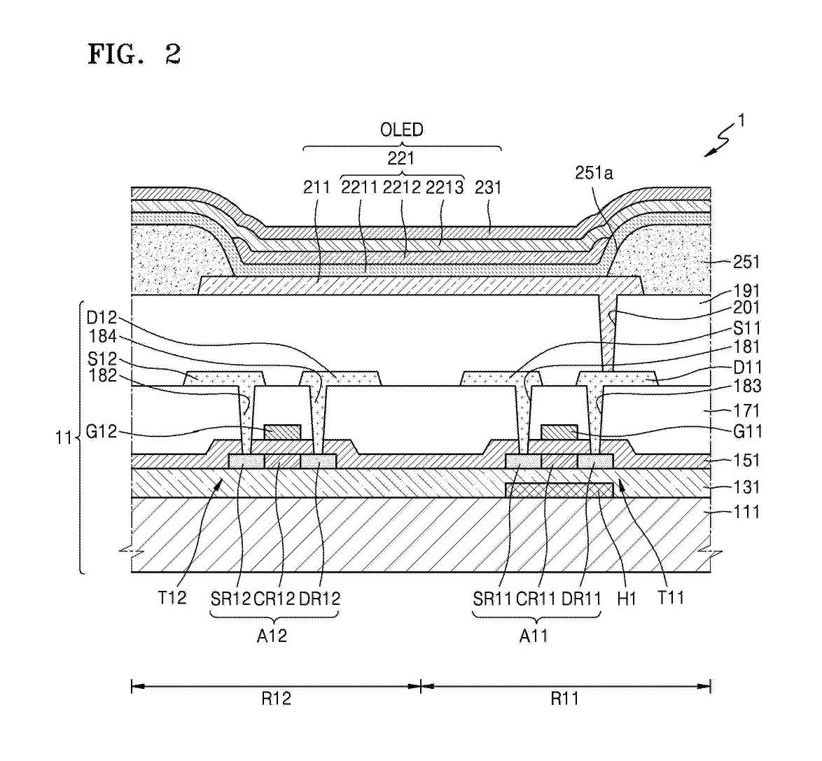

A driving gate electrode G11 of the driving transistor T11 is connected to a lower electrode Cst11 of the capacitor Cst1, a driving source electrode S11 of the driving transistor T11 is connected to a driving power line PL, and a driving drain electrode D11 of the driving transistor T11 is electrically connected to a pixel electrode 211 (see FIG. 2) of the organic light-emitting device OLED of FIG. 2. The driving transistor T11 receives the data signal Data according to a switching operation of the switching transistor T12 and supplies a driving current Id to the organic light-emitting device OLED.

A switching gate electrode G12 of the switching transistor T12 is connected to the scan line SLn, a switching source electrode S12 of the switching transistor T12 is connected to the data line DLm, and a switching drain electrode D12 of the switching transistor T12 is connected to the driving gate electrode G11 of the driving transistor T11. The switching transistor T12 receives the scan signal Scan through the scan line SLn, is turned on according to the scan signal Scan, and performs the switching operation to receive the data signal Data through the data line DLm and to transmit the received data signal Data to the driving gate electrode G11 of the driving transistor T11.

An upper electrode Cst12 of the capacitor Cst1 is connected to the driving power line PL and the lower electrode Cst11 of the capacitor Cst1 is connected to the driving gate electrode G11 of the driving transistor T11. The capacitor Cst1 charges the data signal Data applied to the driving gate electrode G11 of the driving transistor T11 and maintains the data signal Data after the switching transistor T12 is turned off.

The pixel electrode 211 of the organic light-emitting device OLED of FIG. 2 is connected to the driving drain electrode D11 of the driving transistor T11 of FIG. 1, and a common electrode 231 of the organic light-emitting device OLED of FIG. 2 receives a common voltage ELVSS. Accordingly, the organic light-emitting device OLED receives the driving current Id from the driving transistor T11 and emits light to display an image.

FIG. 2 is a cross-sectional view schematically illustrating the organic light-emitting display apparatus according to one exemplary embodiment of the invention.

Referring to FIG. 2, the organic light-emitting display apparatus 1 according to one exemplary embodiment of the invention may include the thin film transistor array substrate 11 and the organic light-emitting device OLED. The thin film transistor array substrate 11 may include a substrate 111 including a driving transistor region R11 and a switching transistor region R12, an additional layer H1 disposed on the substrate 111, a buffer layer 131 disposed on the substrate 111 and covering the additional layer H1, and the driving transistor T11 and the switching transistor T12 disposed in the driving transistor region R11 and the switching transistor region R12, respectively, on the buffer layer 131.

The substrate 111 may include the driving transistor T11 which is disposed in the driving transistor region R11 and the switching transistor T12 which is disposed in the switching transistor region R12. The substrate 111 may include various materials, for example, glass, material or plastic such as polyethylene terephthalate (PET), polyethylene naphthalate (PEN) or polyimide.

The additional layer H1 is disposed in the driving transistor region R11 on the substrate 111. The additional layer H1 may include a material having a high thermal conductivity. For example, the additional layer H1 may include a material having a thermal conductivity in a range from about 104 W/m·° C. to about 106 W/m·° C. The additional layer H1 may be disposed in the driving transistor region R11, but may not be disposed in the switching transistor region R12.

The buffer layer 131 is disposed on the substrate 111 and covers the additional layer H1. The buffer layer 131 may prevent permeation of impurities and flatten a surface of the substrate 111. The buffer layer 131 may include at least one of silicon oxide (SiO₂) and silicon nitride (SiNₓ). According to one exemplary embodiment of the invention, the buffer layer 131 may include a single film of silicon oxide (SiO₂), a single film of silicon nitride (SiNₓ), or a multi-film structure including silicon oxide (SiO₂) and silicon nitride (SiNₓ).

The additional layer H1 may have a higher thermal conductivity than that of the buffer layer 131. That is, the additional layer H1 may have a thermal conductivity higher than that of the silicon oxide (SiO₂) and/or the silicon nitride (SiNₓ) which may be included in the buffer layer 131.

The additional layer H1 may have a higher thermal conductivity than amorphous silicon and/or polysilicon crystallized from the amorphous silicon, which are usable to form a driving active layer A11 of the driving transistor T11, as described below.

The additional layer H1 may include at least one of an organic compound and an inorganic compound. According to one exemplary embodiment of the invention, the additional layer H1 may include at least one selected from a group consisting of siloxane-based materials, graphene, carbon nanotubes, aluminum (Al), molybdenum (Mo), chrome (Cr), silver (Ag), and copper (Cu).

Although not illustrated, a lower buffer layer (not illustrated) may be disposed on the substrate 111. The additional layer H1 may be disposed in the driving transistor region R11 on the lower buffer layer. That is, the lower buffer layer, the additional layer H1, and the buffer layer 131 may be sequentially disposed in the driving transistor region R11 on the substrate 111. When an adhesive force is weak between the substrate 111 and the additional layer H1, intermittent contact phenomena of the additional layer H1 may be prevented by forming the lower buffer layer between the additional layer H1 and an upper side of the substrate 111. The adhesive force between the lower buffer layer and the additional layer H1 may be greater than that between the substrate 111 and the additional layer H1. According to one exemplary embodiment of the invention, the lower buffer layer may include a signal film or a multi film including silicon oxide (SiO₂) and/or silicon nitride (SiNₓ).

The driving transistor T11 is disposed in the driving transistor region R11 on the buffer layer 131, and the switching transistor T12 is disposed in the switching transistor region R12 on the buffer layer 131. The driving transistor T11 and the switching transistor T12 may include the driving active layer A11 and a switching active layer A12, respectively.

The driving active layer A11 may include a driving source area SR11 and a driving drain area DR11, which are doped with impurities, have conductivity, and are spaced apart from each other, and a driving channel area CR11 having a semiconductor material and disposed between the driving source area SR11 and the driving drain area DR11. The switching active layer A12 may include a switching source area SR12 and a switching drain area DR12, which are doped with impurities, have conductivity, and are spaced apart from each other, and a switching channel area CR12 having a semiconductor material and disposed between the driving source area SR12 and the driving drain area DR12.

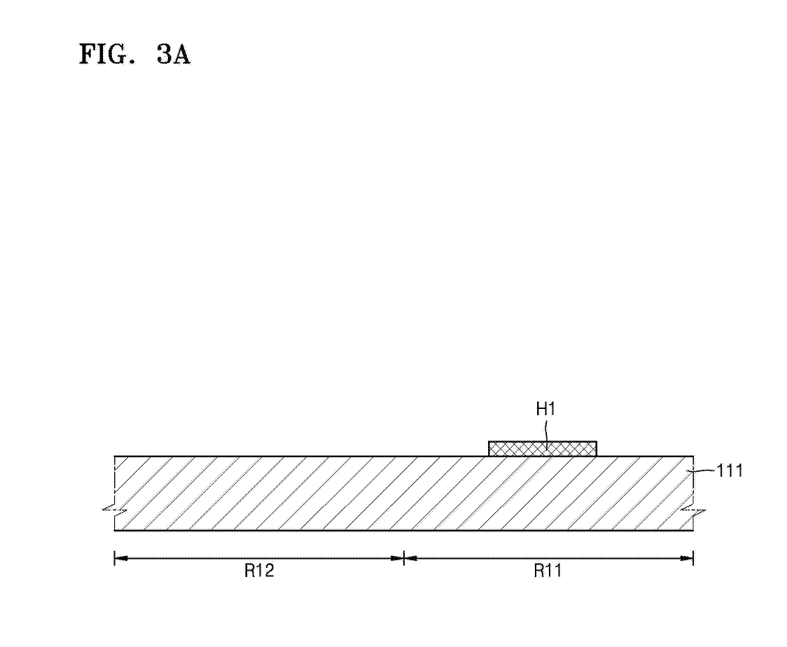

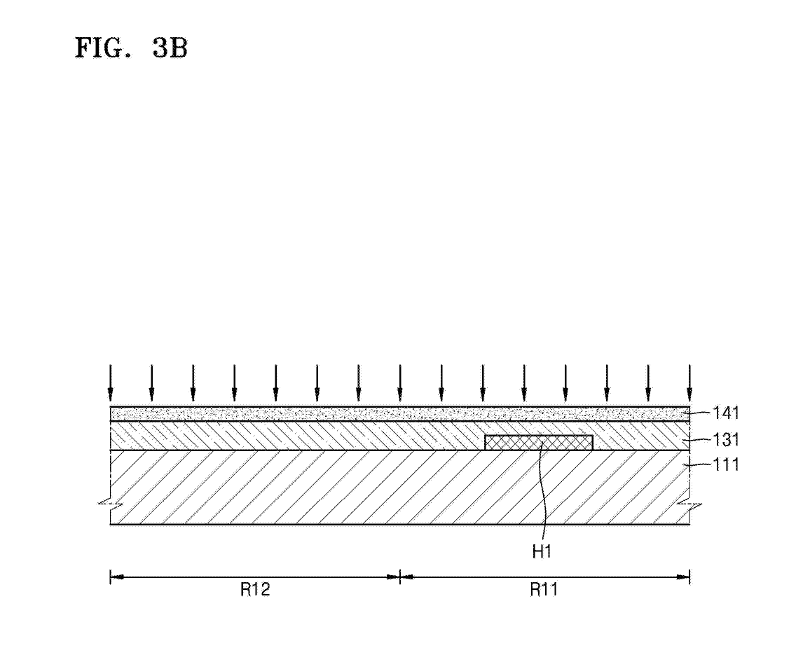

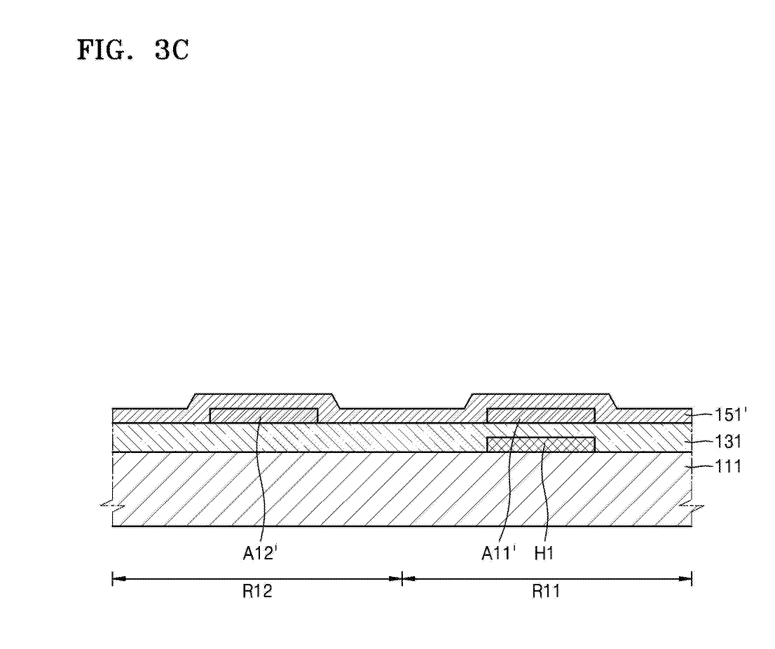

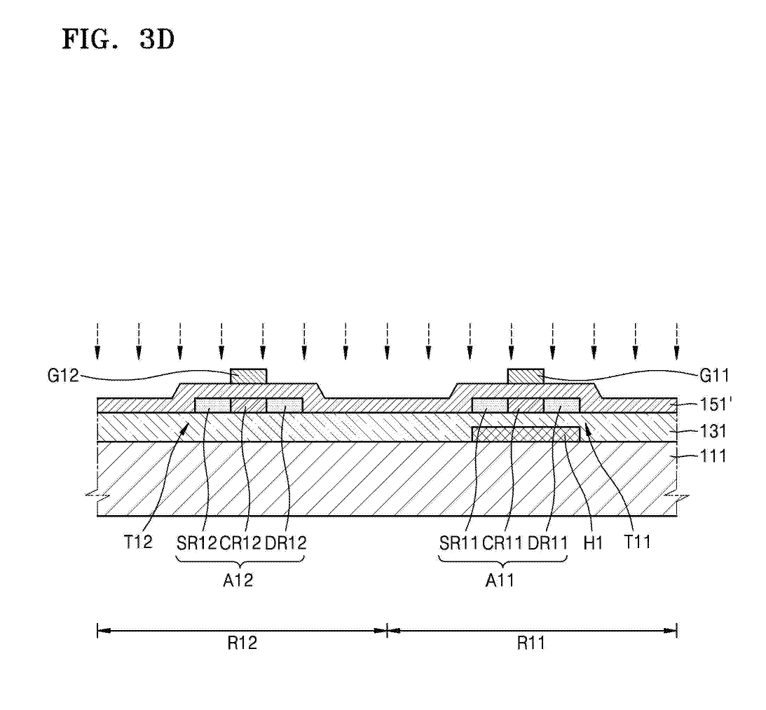

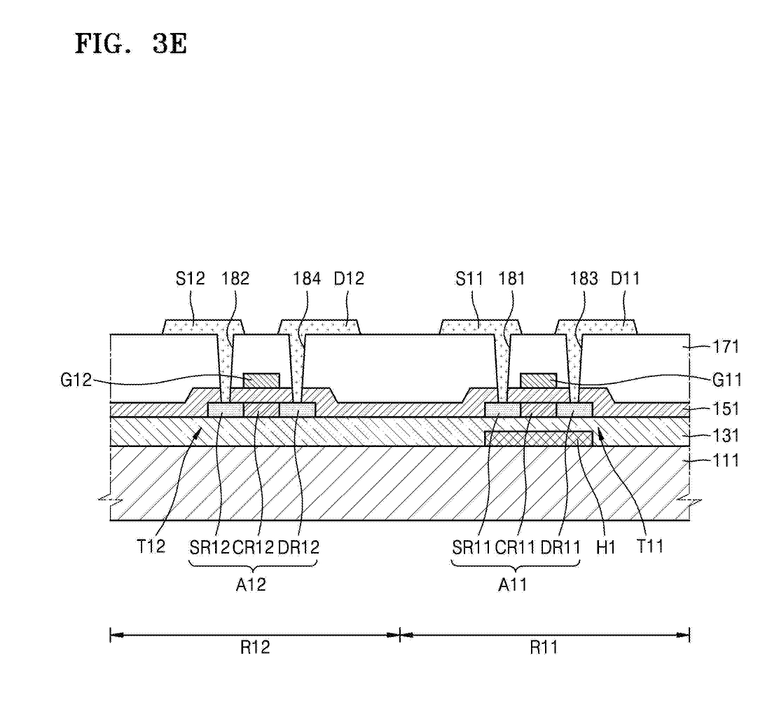

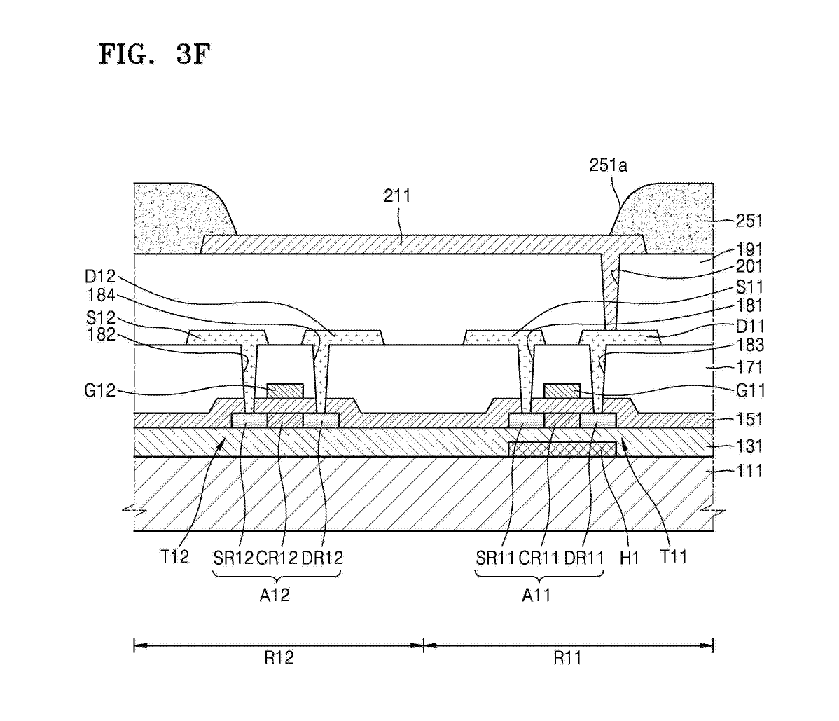

The driving active layer A11 and the switching active layer A12 may be formed from a driving semiconductor layer A11′ of FIG. 3C and a switching semiconductor layer A12′ of FIG. 3C, respectively. The driving semiconductor layer A11′ of FIG. 3C and the switching semiconductor layer A12′ of FIG. 3C may be formed by irradiating with a laser beam an amorphous silicon layer 141 of FIG. 3B disposed on the buffer layer 131, crystallizing the amorphous silicon layer 141 of FIG. 3B into polysilicon, and patterning a polysilicon layer. The laser beam may have an energy density which is sufficient to completely melt the amorphous silicon layer 141 of FIG. 3B.

According to one exemplary embodiment of the invention, the laser beam may be irradiated from above or below the amorphous silicon layer 141 of FIG. 3B in a direction of the amorphous silicon layer 141 of FIG. 3B, as explained below.

Here, since the energy of the laser beam is transmitted to the additional layer H1 disposed in the driving transistor region R11, the dimensions of crystals of the polysilicon forming the driving active layer A11 of the driving transistor T11 may become non-uniform. When the thermal conductivity of the additional layer H1 is increased, the dimensions of the crystals of polysilicon forming the driving active layer A11 of the driving transistor T11 may become more non-uniform.

As stated above, the additional layer H1 may have a higher conductivity than those of the buffer layer 131, which may include silicon oxide (SiO₂) and/or silicon nitride (SiNₓ), and the amorphous silicon to form the driving active layer A11. Accordingly, during a process of irradiating the amorphous silicon layer 141 of FIG. 3B with the laser beam, heat caused by the laser beam may be transmitted to the additional layer H1 easier than to the amorphous silicon layer 141 of FIG. 3B and the buffer layer 131.

When the amorphous silicon is crystallized into the polysilicon, the heat of the laser beam is easily transmitted to the additional layer H1 during the crystallizing process since the additional layer H1 has a higher thermal conductivity than the polysilicon, and thus a smaller amount of the heat is transmitted to the amorphous silicon layer 141 of FIG. 3 corresponding to the driving transistor region R11 than to other regions.

On the other hand, dimensions of crystals of the polysilicon forming the switching active layer A12 of the switching transistor T12 disposed in the switching transistor region R12, in which the additional layer is not disposed, may be substantially uniform.

Similarly, when the dimensions of the crystals of the polysilicon forming the driving active layer A11 become non-uniform, the number of boundaries among crystal grains is increased. That is, transmitting characteristics of the driving channel area CR11 of the driving active layer A11, including the non-uniform polysilicon crystals, may decrease according to the increased number of boundaries of the crystal grains. Therefore, a driving range of the driving transistor T11 may be increased.

The additional layer H1 is disposed on the buffer layer 131 so as to correspond to at least the driving channel area CR11 of the driving active layer A11 and may make the dimensions of the crystals of the polysilicon forming the driving channel area CR11 non-uniform.

Further referring to FIG. 2, a lower gate insulation film 151 is disposed on the buffer layer 131 and covers the driving active layer A11 and the switching active layer A12. The driving gate electrode G11 and the switching gate electrode G12 may be disposed on the lower gate insulation film 151 so as to correspond to at least portions of the driving active layer A11 and the switching active layer A12, respectively.

The lower gate insulation film 151 may include a single layer film including an inorganic compound or an organic compound or a multilayer film. The lower gate insulation film 151, including the single layer film, may be disposed between the driving active layer A11 and the driving gate electrode G11 and between the switching active layer A12 and the switching gate electrode G12, and may include silicon oxide (SiO₂) or silicon nitride (SiNₓ).

Although not illustrated, the lower gate insulation film 151 may include a multilayer film. According to one exemplary embodiment of the invention, the lower gate insulation film 151 may include a lower film including silicon oxide (SiO₂) and an upper film including silicon nitride (SiNₓ). When the silicon nitride (SiNₓ) having a higher etching resistance than the silicon oxide (SiO₂) is disposed on the silicon oxide (SiO₂), damage to the lower gate electrode film 151 may be reduced during a patterning process.

An upper gate insulation film 171 is disposed on the lower gate insulation 151 and covers the driving gate electrode G11 and the switching gate electrode G12.

The lower gate insulation film 151 and the upper gate insulation film 171 may include a driving source contact hole 181, a driving drain contact hole 183, a switching source contact hole 182, and a switching drain contact hole 184 to expose the driving source area SR11, the driving drain area DR11, the switching source area SR12, and the switching drain area DR12, respectively.

The driving source electrode S11 and the driving drain electrode D11 of the driving transistor T11 and the switching source electrode S12 and the switching drain electrode D12 of the switching transistor T12 are disposed on the upper gate insulation film 171. The driving source electrode S11 and the driving drain electrode D11 may be connected to the driving source area SR11 and the driving drain area DR11 through the driving source contact hole 181 and the driving drain contact hole 183, respectively. The switching source electrode S12 and the switching drain electrode D12 may be connected to the switching source area 5R12 and the switching drain area DR12 through the switching source contact hole 182 and the switching drain contact hole 184, respectively.

A via insulation film 191 may be disposed on the upper gate insulation film 171 and cover the driving source electrode S11, the driving drain electrode D11, the switching source electrode S12, and the switching drain electrode D12. According to one exemplary embodiment of the invention, the via insulation film 191 may include an organic compound such as an acryl-based organic compound, polyimide or benzocyclobutene (BCB). The via insulation film 191 may protect components, such as the thin film transistor of the pixel circuit disposed below the via insulation film 191, remove steps formed on the pixel circuit, and planarize an upper surface of the pixel circuit.

The via insulation film 191 may include a via hole 201 to expose the driving drain electrode D11 of the driving transistor T11. The driving drain contact hole 183 of the upper gate insulation film 171 may be filled with the driving drain electrode D11 of the driving transistor T11. The driving drain electrode D11 of the driving transistor T11 and the pixel electrode 211 of the organic light-emitting device OLED may be electrically connected to each other through the via hole 201. That is, the pixel electrode 211 is electrically connected to the driving transistor T11 through the driving drain contact hole 183 and the via hole 201.

The pixel electrode 211 of the organic light-emitting device OLED is disposed on the via insulation film 191. The pixel electrode 211 may include a material having a high work function. According to one exemplary embodiment of the invention, the organic light-emitting display apparatus 1 may be a top emission type so as to display an image in an upper direction of the substrate 111. In this case, the pixel electrode 211 may include a metal reflective film having silver (Ag), magnesium (Mg), aluminum (Al), platinum (Pt), palladium (Pd), gold (Au), nickel (Ni), neodymium (Nd), iridium (Ir), and chrome (Cr), and a transparent conductive film having indium tin oxide (ITO), indium zinc oxide (IZO), zinc oxide (ZnO), and indium tin zinc oxide (ITZO). According to another exemplary embodiment of the invention, the organic light-emitting display apparatus 1 may be a bottom emission type so as to display an image in a lower direction of the substrate 111. In this case, the pixel electrode 211 may include a transparent conductive film having indium tin oxide (ITO), indium zinc oxide (IZO), zinc oxide (ZnO), and indium tin zinc oxide (ITZO), and may include a semi-transparent metal layer.

A pixel definition film 251 may be disposed on the via insulation film 191 to define pixels. The pixel definition film 251 may include a first opening 251a to expose an upper area of the pixel electrode 211 and may cover an edge area of the pixel electrode 211.

An intermediate layer 221 including an organic emission layer 2212 may be disposed on the pixel electrode 211 exposed by the pixel definition film 251. The organic emission layer 2212 may emit red light, green light, blue light, or white light. The intermediate layer 221 may include a lower common layer 2211 disposed between the pixel electrode 211 and the organic emission layer 2212 and an upper common layer 2213 disposed between the organic emission layer 2212 and a common electrode 231.

The lower common layer 2211 may include a hole injection layer and/or a hole transport layer. The upper common layer 2213 may include an electron transport layer and/or an electron injection layer. According to one exemplary embodiment of the invention, one or more various functional layers may be disposed between the pixel electrode 211 and the common electrode 231.

The common electrode 231 may be disposed on the pixel definition film 251 and the intermediate layer 221. The common electrode 231 may include a transparent or semi-transparent electrode if the organic light-emitting display apparatus 1 is a top emission type. The common electrode 231 may include a reflective electrode if the organic light-emitting display apparatus 1 is a bottom emission type.

Although not illustrated, an encapsulation substrate (not illustrated) or an encapsulation layer (not illustrated) may be disposed on the common electrode 231.

According to the above-described embodiment of the invention, the organic light-emitting display apparatus 1 may include the driving transistor T11 disposed in a minimum area and having a wide driving range so as to realize high resolution and an excellent display quality.

Hereinafter, duplicate descriptions will be omitted or briefly added.

FIGS. 3A thru 3F are cross-sectional views illustrating a manufacturing method of the organic light-emitting display apparatus of FIG. 2.

Referring to FIG. 3A, the substrate 111 having the driving transistor region R11 and the switching transistor region R12 is provided, and the additional layer H1 is formed in the driving transistor region R11 of the substrate 111.

After a thermal conductive material is formed on the substrate 111, the additional layer H1 is formed so as to correspond to the driving transistor region R11 by removing at least the thermal conductive material which is disposed in the switching transistor region R12. Although not illustrated, according to one exemplary embodiment of the invention, before the additional layer H1 is formed, a lower buffer layer (not illustrated) may be formed on the substrate 111. An adhesive force between the lower buffer layer and the additional layer H1 may be greater than that between the substrate 111 and the additional layer H1. The intermittent contact phenomena may be prevented by forming the lower buffer layer before forming the additional layer H1.

The thermal conductive material may include a material having a thermal conductivity of about 104 W/m·° C. to about 106 W/m·° C. and may have a higher thermal conductivity than amorphous silicon, polysilicon, silicon oxide (SiO₂), and/or silicon nitride (SiNₓ). The thermal conductive material may include at least one selected from a group consisting of siloxane-based materials, graphene, carbon nanotubes, aluminum (Al), molybdenum (Mo), chrome (Cr), silver (Ag), and copper (Cu), for example.

Referring to FIG. 3B, after the buffer layer 131 is formed on the substrate 111 and covers the additional layer H1, the amorphous silicon layer 141 is formed on the buffer layer 131. The buffer layer 131 may include a material having a lower thermal conductivity than that of the additional layer H1. The buffer layer 131 may include at least one of silicon oxide (SiO₂) and silicon nitride (SiNₓ).

Thereafter, the laser beam is irradiated to crystallize the amorphous silicon layer 141 into polysilicon.

According to one exemplary embodiment of the invention, the laser beam may be irradiated in a direction toward the amorphous silicon layer 141 from above the amorphous silicon layer 141, as illustrated in FIG. 3B.

However, the present invention is not limited thereto. According to another exemplary embodiment of the invention, if the additional layer H1 includes a transparent material, such as siloxane-based materials, graphene, carbon nanotubes, or a semitransparent material, such as aluminum (Al), molybdenum (Mo), chrome (Cr), silver (Ag), and copper (Cu), which is very thin and thin enough to allow transmission of the laser beam, the laser beam may be irradiated from below the amorphous silicon layer 141 toward the amorphous silicon layer 141. That is, the laser beam may pass through the substrate 111, the additional layer H1, and the buffer layer 131, and then be incident on the amorphous silicon layer 141.

Since the additional layer H1 has a higher thermal conductivity than the buffer layer 131 and the amorphous silicon layer 141, heat caused by the laser beam may be transmitted to the additional layer H1 more easily than to the buffer layer 131 and the amorphous silicon layer 141 during the irradiating process.

Also, the additional layer H1 may have a higher thermal conductivity than the polysilicon. Accordingly, during the crystallizing process, the heat caused by the laser beam may be transmitted to the additional layer H1 more easily than to the polysilicon.

Referring to FIG. 3C, the driving semiconductor layer A11′ and the switching semiconductor layer A12′ are respectively formed in the driving transistor region R11 and the switching transistor region R12, respectively, by patterning a layer including the polysilicon. Here, the dimension of crystals of the polysilicon forming the driving semiconductor layer A11′ is more non-uniform than the dimension of crystals of the polysilicon forming the switching semiconductor layer A12′.

By irradiating the laser beam, the amorphous silicon layer 141 may be crystallized into the polysilicon. Here, a smaller amount of heat may be transmitted to the amorphous silicon layer 141 corresponding to the driving transistor region R11 than to the amorphous silicon layer 141 corresponding to the switching transistor region R12 since a portion of heat is transmitted to the additional layer H1 disposed in the driving transistor region R11. Accordingly, a sufficient amount of heat energy is not transmitted to the amorphous silicon layer 141 corresponding to the driving transistor region R11 so that the crystals are not formed uniformly.

Accordingly, the polysilicon of the driving semiconductor layer A11′ may have dimensions that are more non-uniform than the polysilicon of the switching semiconductor layer A12′.

After forming the driving semiconductor layer A11′ and the switching semiconductor layer A12′, a first insulation material 151′ is formed so as to cover the driving semiconductor layer A11′ and the switching semiconductor layer A12′ on the buffer layer 131.

Referring to FIG. 3D, a first conductive material is formed on the first insulation material 151′ and then the first conductive material is patterned to form the driving gate electrode G11 and the switching gate electrode G12. The driving gate electrode G11 and the switching gate electrode G12 may be formed so as to correspond to portions of the driving semiconductor layer A11′ and the switching semiconductor layer A12′, respectively.

Then, the driving semiconductor layer A11′ and the switching semiconductor layer A12′ are doped with ion impurities by using the driving gate electrode G11 and the switching gage electrode G12, respectively, as corresponding masks so as to form the driving active layer A11 and the switching active layer A12.

The driving active layer A11 may include the driving channel area CR11, the driving source area SR11, and the driving drain area DR11. The switching active layer A12 may include the switching channel area CR12, the switching source area SR12, and the switching drain area DR12.

Here, since a transmitting characteristic of the driving channel area CR11 including the polysilicon having non-uniform crystal dimensions decreases, the driving range of the driving transistor T11 increases.

Referring to FIG. 3E, after a second insulation material is formed on the first insulation material 151′ and covers the driving gate electrode G11 and the switching gate electrode G12, the first insulation material 151′ and the second insulation material are patterned to form the lower gate insulation film 151 and the upper gate insulation film 171 including the driving source contact hole 181, the driving drain contact hole 183, the switching source contact hole 182, and the switching drain contact hole 184.

Thereafter, after a second conductive material is formed on the lower gate insulation film 151 and the upper gate insulation film 171, the second conductive material is patterned to form the driving source electrode S11 and the driving drain electrode D11 of the driving transistor T11 and the switching source electrode S12 and the switching drain electrode D12 of the switching transistor T12. The driving source electrode S11 and the driving drain electrode D11 of the driving transistor T11 may be connected to the driving source area SR11 and the driving drain area DR11, respectively, through the driving source contact hole 181 and the driving drain contact hole 183, respectively. The switching source electrode S12 and the switching drain electrode D12 of the switching transistor T12 may be connected to the switching source area SR12 and the switching drain area DR12, respectively, through the switching source contact hole 182 and the switching drain contact hole 184, respectively.

Referring to FIG. 3F, a third insulation material is formed on the upper gate insulation film 171 and covers the driving source electrode S11, the driving drain electrode D11, the switching source electrode S12, and the switching drain electrode D12, and then the third insulation material is patterned to form a via insulation film 191 having the via hole 201.

Thereafter, a third conductive material is formed on the via insulation film 191 and is then patterned to form the pixel electrode 211. A fourth insulation material is formed on the pixel electrode 211 and is then patterned to form the pixel definition film 251 including a first opening 251a to expose a portion of the pixel electrode 211.

Referring back to FIG. 2, the lower common layer 2211 may be formed on the exposed portion of the pixel electrode 211 via the first opening 251a of the pixel definition film 251, and the organic emission layer 2212 may be formed on the lower common layer 2211 so as to correspond to the pixel electrode 211.

Thereafter, the upper common layer 2213 and the common electrode 231 may be formed so as to cover the lower common layer 2211 and the organic emission layer 2212.

The manufacturing method of the thin film transistor array substrate according to one exemplary embodiment of the invention may form the additional layer H1 below the driving transistor T11 without extending a length of the driving channel area CR11 of the driving active layer A11 of the driving transistor T11, and thus a space occupied by the pixel circuit is minimized and a driving range of the driving transistor is increased. That is, the image quality and the resolution of the organic light-emitting display apparatus are increased according to the above described structure.

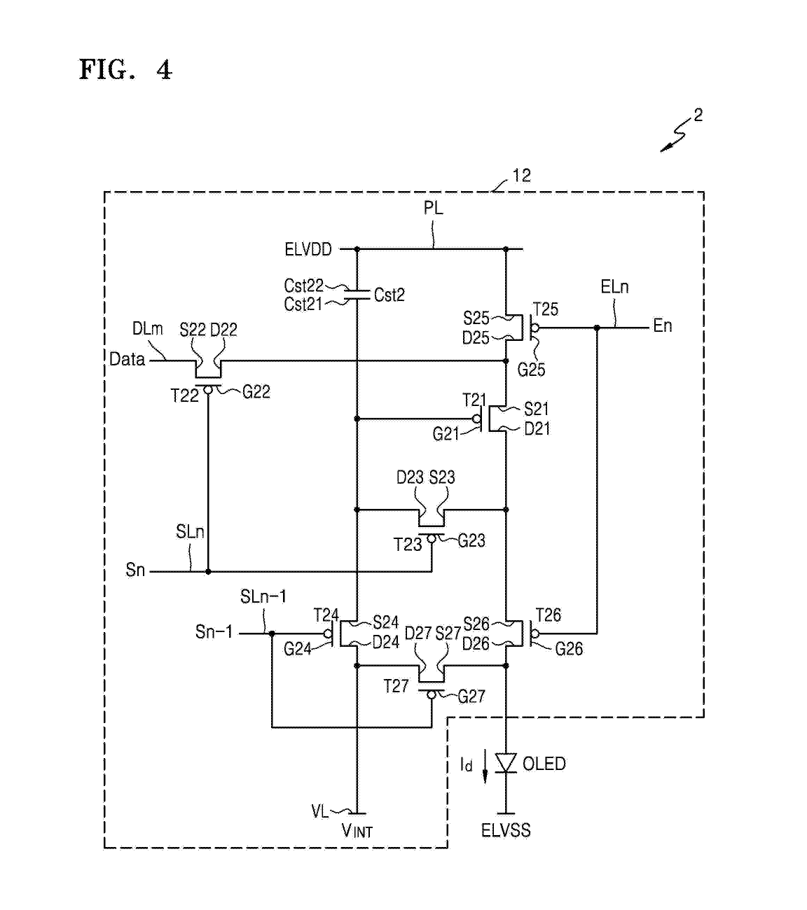

FIG. 4 is an equivalent circuit diagram of a pixel of an organic light-emitting display apparatus according to another exemplary embodiment of the invention.

Referring to FIG. 4, the organic light-emitting display apparatus 2 according to one exemplary embodiment of the invention may include a thin film transistor array substrate 12 and an organic light-emitting device OLED arranged on the thin film transistor array substrate 12. The organic light-emitting display apparatus 2 may include a plurality of pixels, each having the organic light-emitting device OLED. The thin film transistor array substrate 12 may include a pixel circuit to drive each pixel and a plurality of wirings to apply electrical signals to the pixel circuit.

The wirings may include a scan line SLn to transmit a scan signal Sn, a previous scan line SLn−1 to transmit a previous scan signal Sn−1, a data line DLm to transmit a data signal Data, and a driving voltage line PL to transmit a driving voltage ELVDD. However, the present invention is not limited to the above described wiring. As illustrated in FIG. 4, the wiring may further include an initializing voltage line VL to transmit an initializing voltage VINT and an emission control line ELn to transmit an emission control signal En.

Each pixel may include the organic light-emitting device OLED and the pixel circuit to receive signals through the wirings and to drive the organic light-emitting device OLED according to the received signals. According to one exemplary embodiment of the invention, the pixel circuit may include seven transistors T21 thru T27 and one capacitor Cst2. The transistors T21 thru T27 may be referred to as a driving transistor T21, a switching transistor T22, a compensating transistor T23, a first initializing transistor T24, an operation controlling transistor T25, an emission controlling transistor T26, and a second initializing transistor T27.

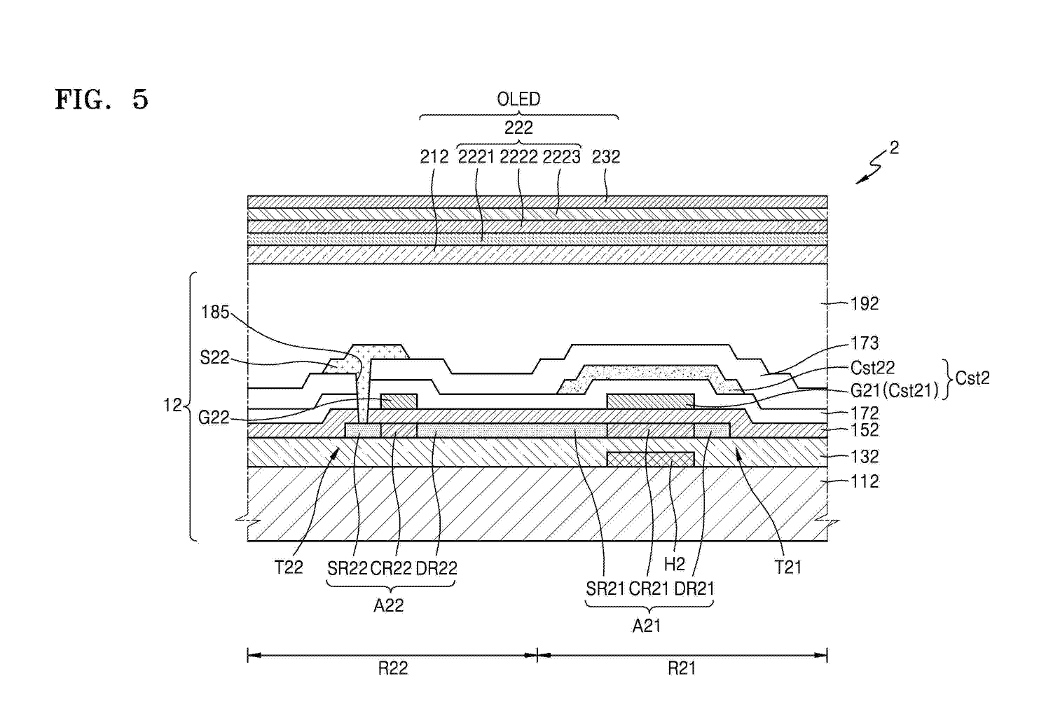

A driving gate electrode G21 of the driving transistor T21 is connected to a lower electrode Cst21 of the capacitor Cst2, a driving source electrode S21 of the driving transistor T21 is connected to a driving power line PL through an operation controlling transistor T25, and a driving drain electrode D21 of the driving transistor T21 is electrically connected to a pixel electrode 212 of the organic light-emitting device OLED of FIG. 5 through an emission controlling transistor T26. The driving transistor T21 receives the data signal Data according to a switching operation of the switching transistor T22 and supplies a driving current Id to the organic light-emitting device OLED via emission controlling transistor T26.

A switching gate electrode G22 of the switching transistor T22 is connected to the scan line SLn, a switching source electrode S22 of the switching transistor T22 is connected to the data line DLm, and a switching drain electrode D22 of the switching transistor T22 is connected to the driving source electrode S21 of the driving transistor T21, and is also connected to the driving power line PL through the operation controlling transistor T25. The switching transistor T22 receives the scan signal Sn through the scan line SLn, is turned on according to the scan signal Sn, and performs the switching operation to receive the data signal Data through the data line DLm and to transmit the received data signal Data to the driving source electrode S21 of the driving transistor T21.

A compensating gate electrode G23 of the compensating transistor T23 is connected to the scan line SLn, a compensating source electrode S23 of the compensating transistor T23 is connected the driving drain electrode D21 of the driving transistor T21 and is also connected to the pixel electrode 212 of the organic light-emitting device OLED of FIG. 5 through the emission controlling transistor T26. A compensating drain electrode D23 of the compensating transistor T23 is connected to the lower electrode Cst21 of the capacitor Cst2, to a first initializing source electrode S24 of the first initializing transistor T24, and to the driving gate electrode G21 of the driving transistor T21. The compensating transistor T23 receives the scan signal Sn through the scan line SLn, is turned on according to the received scan signal Sn, and connects the driving gate electrode G21 of the driving transistor T21 to the driving drain electrode D21 of the driving transistor T21 so as to form a diode connection of the driving transistor T21.

A first initializing gate electrode G24 of the first initializing transistor T24 is connected to the previous scan line SLn−1, and a first initializing drain electrode D24 of the first initializing transistor T24 is connected to the initializing voltage line VL. The initializing source electrode S24 of the first initializing transistor T24 is connected to the lower electrode Cst21 of the capacitor Cst2, to the compensating drain electrode D23 of the compensating transistor T23, and to the driving gate electrode G21 of the driving transistor T21. The first initializing transistor T24 receives the previous scan signal Sn−1 through the previous scan line SLn−1, is turned on according to the received previous scan signal Sn−1, and transmits the initializing voltage VINT to the driving gate electrode G21 of the driving transistor T21 so as to perform an initializing operation to initialize a voltage of the driving gate electrode G21 of the driving transistor T21.

An operation controlling gate electrode G25 of the operation controlling transistor T25 is connect to the emission controlling line ELn. An operation controlling source electrode S25 of the operation controlling transistor T25 is connected to the driving voltage line PL, and an operation controlling drain electrode D25 of the operation controlling transistor T25 is connected to the driving source electrode S21 of the driving transistor T21 and the switching drain electrode D22 of the switching transistor T22. The operation controlling transistor T25 connects the driving voltage line PL and the driving transistor T21. The operation controlling transistor T25 is turned on according to the emission controlling signal En transmitted through the emission controlling line ELn and transmits the driving voltage ELVDD to the driving transistor T21.

An emission controlling gate electrode G26 of the emission controlling transistor T26 is connected to the emission controlling line ELn, and an emission controlling source electrode S26 of the emission controlling transistor T26 is connected to the driving drain electrode D21 of the driving transistor T21 and to the compensating source electrode S23 of the compensating transistor T23. An emission controlling drain electrode D26 of the emission controlling transistor T26 is electrically connected to the pixel electrode 212 of the organic light-emitting device OLED of FIG. 5. The operation controlling transistor T25 and the emission controlling transistor T26 receive the emission controlling signal En through the emission controlling line ELn, are simultaneously turned on, and transmit the driving voltage ELVDD to the organic light-emitting device OLED so that the driving current Id flows to the organic light-emitting device OLED.

A second initializing gate electrode G27 of the second initializing transistor T27 is connected to the previous scan line SLn−1. A second initializing source electrode S27 of the second initializing transistor T27 is connected to the pixel electrode 212 of the organic light-emitting device OLED of FIG. 5. A second initializing drain electrode D27 of the second initializing transistor T27 is connected to the initializing voltage line VL. The second initializing transistor T27 receives the previous scan signal Sn−1 through the previous scan line SLn−1, is turned on according to the received previous scan signal Sn−1, and initializes the pixel electrode 212 of the organic light-emitting device OLED of FIG. 5.

According to the present embodiments of the invention, the first initializing transistor T24 and the second initializing transistor T27 are connected to the previous scan line SLn− but the present invention is not limited thereto. According to another exemplary embodiment of the invention, the first initializing transistor T24 may be connected to the previous scan line SLn−1 and operates according to the previous scan signal Sn−1, and the second initializing transistor T27 may be connected to a separate wiring and operate according to a signal transmitted through the separate wiring.

An upper electrode Cst22 of the capacitor Cst2 is connected to the driving power line PL, and a common electrode 232 of the organic light-emitting device OLED of FIG. 5 receives a common voltage ELVSS. Accordingly, the organic light-emitting device OLED receives the driving current Id from the driving transistor T21 so as to emit light to display an image.

FIG. 5 is a cross-sectional view schematically illustrating the organic light-emitting display apparatus according to another exemplary embodiment of the invention.

Referring to FIG. 5, the organic light-emitting display apparatus 2 according to another exemplary embodiment of the invention may include the thin film transistor array substrate 12 and the organic light-emitting device OLED disposed on the thin film transistor array substrate 12. The thin film transistor array substrate 12 may include a substrate 112 including a driving transistor region R21 and a switching transistor region R22, an additional layer H2 disposed in the driving transistor region R21 on the substrate 112, a buffer layer 132 disposed on the substrate 112 and covering the additional layer H2, and the driving transistor T21 and the switching transistor T22 disposed in the driving transistor region R21 and the switching transistor region R22, respectively, on the buffer layer 132. According to one exemplary embodiment of the invention, the organic light-emitting display apparatus 2 further includes a capacitor Cst2. The capacitor Cst2 may include a lower electrode Cst21 functioning as the driving gate electrode G21 and an upper electrode Cst22 disposed so as to correspond to the driving gate electrode G21.

The substrate 112 may include the driving transistor region R21, in which the driving transistor T21 is disposed, and the switching transistor region R22, in which the switching transistor T22 is disposed.

The additional layer H2 is disposed in the driving transistor region R21 on the substrate 112. The additional layer H2 may include a material having a high thermal conductivity. For example, the additional layer H2 may include a material having a thermal conductivity in a range from about 104 W/m ° C. to about 106 W/m ° C. The additional layer H2 may be disposed in the driving transistor region R21, but may not be disposed in the switching transistor region R22.

The buffer layer 132 is disposed on the substrate 112 and covers the additional layer H2. The additional layer H2 may have a higher thermal conductivity than the buffer layer 132.

Although not illustrated, a lower buffer layer (not illustrated) may be disposed on the substrate 112. The additional layer H2 may be disposed on the lower buffer layer in the driving transistor region R21.

The additional layer H2 may include at least one of an organic compound and an inorganic compound. According to one exemplary embodiment of the invention, the additional layer H2 may include at least one selected from a group consisting of siloxane-based materials, graphene, carbon nanotubes, aluminum (Al), molybdenum (Mo), chrome (Cr), silver (Ag), and copper (Cu).

The driving transistor T21 is disposed on the buffer layer 132 in the driving transistor region R21, and the switching transistor T22 is disposed on the buffer layer 132 in the switching transistor region R22. The driving transistor T21 and the switching transistor T22 may include the driving active layer A21 and a switching active layer A22, respectively.

The driving active layer A21 may include a driving source area SR21, a driving drain area DR21, and a driving channel area CR21. The switching active layer A22 may include a switching source area SR22, a switching drain area DR22, and a switching channel area CR22.

As illustrated in FIG. 5, the driving source area SR21 of the driving transistor T21 is electrically connected to the switching drain area DR22 of the switching transistor T22.

The driving active layer A21 and the switching active layer A22 may be formed from a driving semiconductor layer (not illustrated) and a switching semiconductor layer (not illustrated), respectively. The driving semiconductor layer and the switching semiconductor layer may be formed by irradiating with a laser beam an amorphous silicon layer (not illustrated) disposed on the buffer layer 132, crystallizing the amorphous silicon layer into polysilicon, and patterning a polysilicon layer. The laser beam may have an energy density sufficient to completely melt the amorphous silicon layer. The laser beam may be irradiated from above or below the amorphous silicon layer in a direction of the amorphous silicon layer.

Here, since the energy of the laser beam is transmitted to the additional layer H2 disposed in the driving transistor region R21, the dimensions of crystals of the polysilicon forming the driving active layer A21 of the driving transistor T21 may become non-uniform. When the thermal conductivity of the additional layer H2 is greater, the dimensions of the crystals of polysilicon forming the driving active layer A21 of the driving transistor T21 may become more non-uniform.

During a process of irradiating the amorphous silicon layer (not illustrated) with the laser beam, heat caused by the laser beam may be transmitted to the additional layer H2 easier than to the amorphous silicon layer and the buffer layer 132. When the amorphous silicon is crystallized into the polysilicon, the heat caused by the laser beam is transmitted to the additional layer H2 more easily than to the polysilicon during the crystallizing process. Accordingly, a smaller amount of the heat is transmitted to the amorphous silicon layer corresponding to the driving transistor region R21 than other region.

On the other hand, dimensions of crystals of the polysilicon forming the switching active layer A22 of the switching transistor T22 disposed in the switching transistor region R22 in which the additional layer H2 is not disposed may be substantially uniform.

When the dimensions of the crystals of the polysilicon to form the driving active layer A21 become non-uniform, transmitting characteristics of the driving channel area CR21 decrease, and thus a driving range of the driving transistor T21 becomes increased.

The additional layer H2 is disposed so as to correspond to at least the driving channel area CR21 of the driving active layer A21 and may make the dimensions of the crystals of the polysilicon forming the driving channel area CR21 non-uniform.

A lower gate insulation film 152 is disposed on the buffer layer 132 and covers the driving active layer A21 and the switching active layer A22. The driving gate electrode G21 and the switching gate electrode G22 may be disposed on the lower gate insulation film 152 so as to correspond to at least portions of the driving active layer A21 and the switching active layer A22, respectively.

The driving gate electrode G21 may function as the lower electrode Cst21 of the capacitor Cst2.

An upper gate insulation film 172 is disposed on the lower gate insulation film 152 and covers the driving gate electrode G21 and the switching gate electrode G22.

The upper electrode Cst22 of capacitor Cst2 may be disposed on the upper gate insulation film 172 in the driving transistor region R21. The capacitor Cst2 may be disposed so as to overlap the driving transistor T21 in a planar view. That is, the capacitor Cst2 may include the driving gate electrode G21 functioning as the lower electrode Cst21 and the upper electrode Cst22 disposed so as to correspond to the driving gate electrode G21. The lower electrode Cst21 and the upper electrode Cst22 are disposed opposite to each other with respect to the upper gate insulation film 172. When areas of the lower electrode Cst21 and the upper electrode Cst22 of the capacitor Cst2 are increased, the capacitance of the capacitor Cst2 becomes increased.

According to one exemplary embodiment of the invention, the capacitor Cst2 may be disposed so as to overlap the driving transistor T21 to reduce a space occupied by the capacitor Cst2 and to increase the capacitance of the capacitor Cst2. An interlayer insulation film 173 may be disposed on the upper gate insulation film 172 so as to cover the upper electrode Cst22.

The lower gate insulation film 152, the upper gate insulation film 172, and the interlayer insulation film 173 may include a switching source contact hole 185 to expose the switching source area SR22.

The switching source electrode S22 of the switching transistor T22 may be disposed on the interlayer insulation film 173. The switching source electrode S22 may be connected to the switching source area SR22 through the switching source contact hole 185. The switching source electrode S22 may be electrically connected to the data line DLm of FIG. 4.

A via insulation film 192 may be disposed on the interlayer insulation film 173 so as to cover the switching source electrode S22, and the pixel electrode 212 of the organic light-emitting device OLED may be disposed on the via insulation film 192. The pixel electrode 212 may include a material having a high work function and may include at least one of a metal reflective film and a transparent conductive film.

Although not illustrated, a pixel definition film (not illustrated) may be disposed on the via insulation film 192 so as to define the respective pixels. The pixel definition film may have an opening (not illustrated) so as to expose an upper side of the pixel electrode 212 and may cover an edge portion of the pixel electrode 212.

An intermediate layer 222 including an organic emission layer 2222 may be disposed on the pixel electrode 212 which is exposed by the pixel definition film. The intermediate layer 222 may include a lower common layer 2221 disposed between the pixel electrode 212 and the organic emission layer 2222, and an upper common layer 2223 disposed between the organic emission layer 2222 and the common electrode 232.

The common electrode 232 may be disposed on the pixel definition film and the intermediate layer 222. The organic light-emitting device OLED may include the pixel electrode 212, the intermediate layer 222, and the common electrode 232.

Although not illustrated, an encapsulation substrate (not illustrated) or an encapsulation layer (not illustrated) may be disposed on the common electrode 232.

According to the above described embodiments of the invention, since boundaries of the polysilicon crystal grains forming the driving active layer are increased and transmitting characteristics of the driving channel area are decreased, a driving range of the driving transistor may be increased without increasing a length of the driving channel area. According to the improved driving range of the driving transistor, the gradation of light emitted from the organic light-emitting device is fine-controlled so as to facilitate a display quality and a high resolution in the organic light-emitting display apparatus.

It should be understood that exemplary embodiments of the invention described herein should be considered in a descriptive sense only and not for purposes of limitation. Descriptions of features or aspects within each exemplary embodiment of the invention should typically be considered as available for other similar features or aspects in other exemplary embodiments of the invention.

While one or more exemplary embodiments of the invention have been described with reference to the figures, it will be understood by those of ordinary skill in the art that various changes in form and detail may be made therein without departing from the spirit and scope as defined by the following claims.

What is claimed is:

1. A thin film transistor array substrate, comprising:
a substrate including a driving transistor region and a switching transistor region;
an additional layer disposed in the driving transistor region on the substrate;
a buffer layer covering the additional layer on the substrate; and
a driving transistor and a switching transistor in the driving transistor region and the switching transistor region, respectively, on the buffer layer.

2. The thin film transistor array substrate of claim 1, wherein the additional layer has a thermal conductivity in a range from about 104 W/m·° C. to about 106 W/m·° C.

3. The thin film transistor array substrate of claim 1, wherein the additional layer has a thermal conductivity higher than a thermal conductivity of the buffer layer.

4. The thin film transistor array substrate of claim 1, wherein the additional layer has a thermal conductivity higher than a thermal conductivity of at least one material selected from a group consisting of silicon oxide (SiO₂), silicon nitride (SiNₓ), amorphous silicon, and polysilicon.

5. The thin film transistor array substrate of claim 1, wherein the additional layer comprises at least one selected from a group consisting of siloxane-based materials, graphene, carbon nanotubes, aluminum (Al), molybdenum (Mo), chrome (Cr), silver (Ag), and copper (Cu).

6. The thin film transistor array substrate of claim 1, wherein the buffer layer comprises at least one of silicon oxide (SiO₂) and silicon nitride (SiNₓ).

7. The thin film transistor array substrate of claim 1, wherein:
the driving transistor comprises a driving active layer disposed on the buffer layer so as to correspond to the additional layer and a driving gate electrode disposed on a portion of the driving active layer;
the switching transistor comprises a switching active layer disposed on the buffer layer and a switching gate electrode disposed on a portion of the switching active layer; and
the driving active layer comprises crystals having more non-uniform dimensions than non-uniform dimensions of the switching active layer.

8. The thin film transistor array substrate of claim 7, further comprising a capacitor overlapping the driving transistor in a direction perpendicular to the substrate;
wherein the capacitor comprises the driving gate electrode functioning as a lower electrode of the capacitor, and an upper electrode corresponding to the driving gate electrode.

9. The thin film transistor array substrate of claim 7, wherein the driving active layer comprises a driving source area, a driving drain area spaced apart from the driving source area, and a driving channel area disposed between the driving source area and the driving drain area; and
wherein the additional layer is disposed between the substrate and at least a portion of the driving channel area.

10. A manufacturing method of a thin film transistor array substrate, the method comprising the steps of:
forming an additional layer in a driving transistor region on a substrate having the driving transistor region and a switching transistor region;
forming a buffer layer on the substrate so as to cover the additional layer;
forming an amorphous silicon layer on the buffer layer;
irradiating the amorphous silicon layer with a laser beam so as to crystallize the amorphous silicon layer into polysilicon;
patterning a polysilicon layer and forming a driving semiconductor layer and a switching semiconductor layer in the driving transistor region and the switching transistor region, respectively;
forming a lower gate insulation film so as to cover the driving semiconductor layer and the switching semiconductor layer;
forming a driving gate electrode and a switching gate electrode on the lower gate insulation film so as to correspond to a portion of the driving semiconductor layer and a portion of the switching semiconductor layer, respectively; and
doping the driving semiconductor layer and the switching semiconductor layer by using the driving gate electrode and the switching gate electrode as corresponding masks, forming a driving active layer including a driving source area, a driving drain area, and a driving channel area, and forming a switching active layer including a switching source area, a switching drain area, and a switching channel area.

11. The manufacturing method of claim 10, wherein the step of forming the additional layer comprises:
forming a thermal conductive material on the substrate; and
removing the thermal conductive material from the switching transistor region, and forming the additional layer so as to correspond to the driving transistor region.

12. The manufacturing method of claim 10, further comprising the step of providing the additional layer with a thermal conductivity higher than that of the buffer layer.

13. The manufacturing method of claim 10, further comprising the step of providing the additional layer with a thermal conductivity higher than a thermal conductivity of at least one material selected from a group consisting of amorphous silicon, polysilicon, silicon oxide (SiO₂), and silicon nitride (SiNₓ).

14. The manufacturing method of claim 10, further comprising the step of providing the additional layer with a thermal conductivity in a range from about 104 W/m·° C. to about 106 W/m·° C.

15. The manufacturing method of claim 10, wherein the additional layer comprises at least one selected from a group consisting of siloxane-based materials, graphene, carbon nanotubes, aluminum (Al), molybdenum (Mo), chrome (Cr), silver (Ag), and copper (Cu).

16. The manufacturing method of claim 10, wherein the buffer layer comprises at least one of silicon oxide (SiO₂) and silicon nitride (SiNₓ).

17. An organic light-emitting display apparatus, comprising:
a substrate including a driving transistor region and a switching transistor region;
an additional layer disposed in the driving transistor region on the substrate;
a buffer layer covering the additional layer on the substrate;
a driving transistor and a switching transistor disposed in the driving transistor region and the switching transistor region, respectively, on the buffer layer;
a pixel electrode electrically connected to the driving transistor;
a common electrode corresponding to the pixel electrode; and
an organic emission layer disposed between the pixel electrode and the common electrode.

18. The organic light-emitting display apparatus of claim 17, wherein the additional layer has a thermal conductivity in a range from about 104 W/m·° C. to about 106 W/m·° C.

19. The organic light-emitting display apparatus of claim 17, wherein:
the driving transistor comprises a driving active layer disposed on the buffer layer so as to correspond to the additional layer and a driving gate electrode disposed on a portion of the driving active layer;
the switching transistor comprises a switching active layer disposed on the buffer layer and a switching gate electrode disposed on a portion of the switching active layer; and
the driving active layer comprises crystals having more non-uniform dimensions than non-uniform dimensions of the switching active layer.

20. The organic light-emitting display apparatus of claim 19, further comprising a capacitor overlapping the driving transistor in a direction perpendicular to the substrate;
wherein the capacitor comprises the driving gate electrode functioning as a lower electrode of the capacitor, and an upper electrode corresponding to the driving gate electrode.
